(19) United States
(12) Patent Application Publication
(10) Pub. No.: US 2025/0060431 A1
(43) Pub. Date: Feb. 20, 2025

(54) Solid State Spin Sensor for Battery Inspection

(71) Applicants: David Glenn, Cambridge, MA (US); Cole Meisenhelder, Washington, DC (US)

(72) Inventors: David Glenn, Cambridge, MA (US); Cole Meisenhelder, Washington, DC (US)

(21) Appl. No.: 18/809,320

(22) Filed: Aug. 19, 2024

Related U.S. Application Data
(60) Provisional application No. 63/520,283, filed on Aug. 17, 2023.

(51) Int. Cl. G01R 33/26; G01R 15/24; G01R 31/389

(52) U.S. Cl. CPC G01R 33/26; G01R 15/245; G01R 31/389

(57) ABSTRACT

A solid-state spin sensor system for battery inspection is disclosed for detecting magnetic fields generated by currents within a battery. The system comprises a solid-state substrate, typically diamond, embedded with an ensemble of color centers such as a nitrogen-vacancy centers. It includes a magnetic field generator to provide a bias magnetic field, an optical driving system to optically excite the defect, and an optical sensor to measure the fluorescence intensity. The control system controls the current flowing between the battery terminals and generates a spatially resolved map of the magnetic field produced by this current, allowing for the identification of defects.

### CROSS-REFERENCE TO RELATED APPLICATIONS

This patent application claims the benefit of priority to U.S. Provisional Patent Application No. 63/520,283, filed on Aug. 17, 2023 and U.S. Provisional Patent Application No. 63/608,302, filed on Dec. 11, 2023, each of which is incorporated by reference herein in its entirety.

### TECHNICAL FIELD

The present disclosure relates to quantum sensing technologies, specifically to the use of solid-state spin sensors for the inspection and defect identification in batteries.

### BACKGROUND

The evaluation and inspection of batteries, particularly for identifying defects and imperfections, are important processes in both research and development and in manufacturing quality control. Traditional inspection methods, including X-ray imaging and scanning electron microscopy, frequently fall short in terms of throughput and dynamic range, especially when it comes to detecting the magnetic fields generated by currents within a battery.

Presently established magnetic imaging methods, such as magnetic force microscopy (MFM) and scanning superconducting quantum interference device (SQUID) microscopy, either lack adequate spatial resolution or are incapable of detecting small variations in magnetic fields due to their insufficient dynamic range. These limitations present challenges in accurately mapping the current distribution within batteries to identify manufacturing defects, damage, or other anomalies.

There is a need for an improved inspection tool that combines high dynamic range with fine spatial resolution in a non-destructive manner. Such a tool would facilitate effective defect identification in batteries while maintaining the form factor of commercial battery cells. The solid-state spin sensor for battery inspection described herein addresses these needs by providing a robust solution for the precise and effective inspection of batteries.

### SUMMARY

The present disclosure relates to systems and methods for detecting defects in batteries using quantum sensors. The disclosed system includes a test circuit to control the current between the cathode and the anode of a battery, a solid-state substrate containing an embedded color center, and various components designed to generate and measure specific physical responses induced by the current.

The system further includes a magnetic field generator to produce a bias magnetic field at the location of the defect in the solid-state substrate and an optical driving system to optically excite the defect. An optical sensor measures the fluorescence intensity of the defect, and a control system processes these measurements to create a spatially resolved map of the magnetic field generated by the current. This map is then analyzed to identify defects within the battery, enhancing reliability and detection precision.

The system utilizes a microwave driving system to perform frequency sweeps and identify resonance frequencies to generate the spatially resolved map. Embodiments include measuring multiple magnetic field components to generate a spatially resolved vector magnetic field map, employing machine learning algorithms to improve defect identification and create training data sets, and using a three-axis stage to scan the battery and collect magnetic field data to produce comprehensive tiled images.

Disclosed methods provide process steps for implementing the defect detection system. These include controlling current, generating magnetic fields, optically exciting defects, measuring fluorescence, and generating spatially resolved maps to identify defects. Additional methods include using a microwave driving system to induce spin transitions, and incorporating machine learning algorithms to predict the presence of defects.

### BRIEF DESCRIPTION OF DRAWINGS

The foregoing and other objects, aspects, features, and advantages of the disclosure will become more apparent and better understood by referring to the following description taken in conjunction with the accompanying drawings, in which:

FIG. 1A is a side view of a solid-state spin sensor for battery inspection;

FIG. 1B is a perspective view of a solid-state spin sensor for battery inspection;

FIG. 2 is a perspective view of an objective and solid-state substrate, illustrating an optical axis and focal plane;

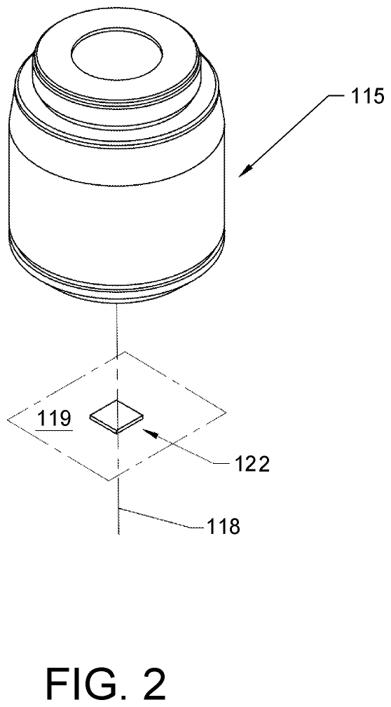

FIG. 3 is a bottom view of a sensor head and microwave driving system;

FIG. 4 is a block diagram of a solid-state spin sensor for battery inspection, in accordance with certain embodiments;

FIG. 5a is a spatially resolved map of a magnetic field associated with a defect-free electrode;

FIG. 5b is a spatially resolved map of a magnetic field associated with a defective electrode;

FIG. 6 is a flow chart of a process for inspecting a battery using a solid-state spin sensor; and

FIG. 7 is a flow chart of a subprocess for estimating magnetic vectors due to current.

### DETAILED DESCRIPTION

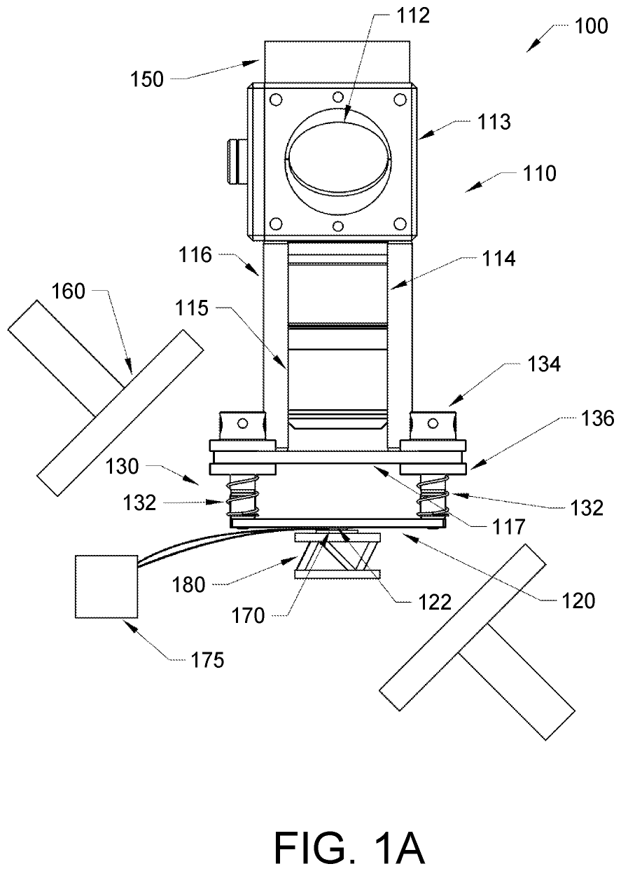

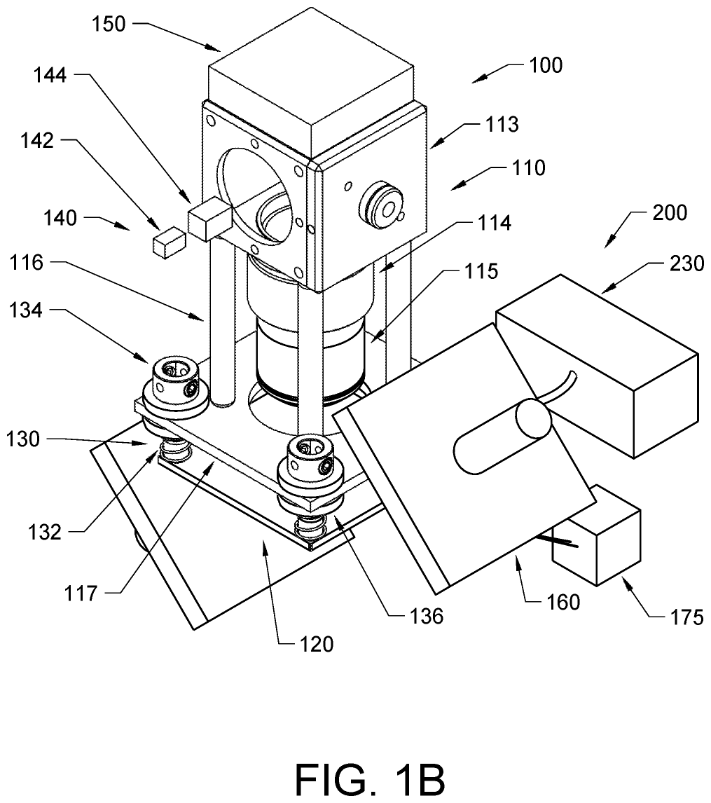

Turning now to the detailed description, FIG. 1A depicts an embodiment of a solid-state spin sensor 100. The solid-state spin sensor 100 leverages the quantum properties of a fluorescent color center ensemble embedded within a solid-state substrate 122 to measure and map magnetic fields produced by a battery 170 with high precision. The color center ensemble is typically situated in a plane near a battery-facing surface of the solid-state substrate 122.

The solid-state spin sensor 100 includes an optical microscope 110, which provides optical components to facilitate imaging of the color center ensemble. In an embodiment the solid-state substrate 122 is a single crystal diamond, and the color centers are nitrogen vacancy (NV) centers. In another embodiment the solid-state substrate 122 is silicon carbide, and the color centers are divacancies.

Referring now to FIG. 1B, an optical driving system 140 supplies an optical driving field to the color center ensemble that effects optical transitions in the color centers. The optical driving system 140 is typically used to excite the color centers in the color center ensemble for measurement readout and spin initialization. In the depicted embodiment the optical driving system 140 includes a pump laser 142 and an acousto-optic modulator 144 to modulate light emitted by the laser 142, thereby providing enhanced control over the optical excitation of the ensemble of color centers. In an embodiment the laser 142 emits coherent light with a 532 nm wavelength. In another embodiment the optical driving field is generated by a light emitting diode.

An optical sensor 150 captures images of the light fluoresced by the color center ensemble and magnified by the optical microscope 110. The captured image data facilitates the analysis and interpretation of spin states as they correlate to local magnetic fields produced by the battery 170. In an embodiment, fiducial markers are situated substantially coplanar with the color center ensemble, and the optical sensor 150 captures images of the fiducial markers to assist in aligning the color center ensemble with the focal plane 119. Fiducial markers according to this embodiment can be, for example, a set of crosshairs burned into the color center ensemble with a pulsed laser or an array of gold nanoparticles milled into the surface of the solid-state substrate 122 to a depth matching the depth of the color center ensemble.

In an embodiment the optical sensor 150 includes a CCD or CMOS type sensor to capture spatially resolved fluorescence data from the color center ensemble. In another embodiment optical sensor 150 includes a photodiode to capture fluorescence data from the color center ensemble, which is considered as a single point.

A dichroic mirror 112 (shown in FIG. 1A) is provided in the optical path between the optical microscope 110 and the optical sensor 150. In the depicted embodiment, the dichroic mirror 112 facilitates the optical pumping of the ensemble of color centers by the optical driving system 140, while enabling the optical sensor 150 to detect fluoresced light from the ensemble of color centers without obfuscation by the excitation light emitted by pump the laser 142. In an embodiment the color center ensemble is excited with green light and fluoresces red light, and thus a longpass dichroic mirror 112 is utilized.

The dichroic mirror 112 is mounted in a cage cube 113, which also includes openings for each of the optical driving system 140, the optical sensor 150, and a parfocal length extender 114. The microscope objective 115 is mounted to the parfocal length extender 114 at the end opposite the cage cube 113. In an embodiment, additional optical filters are situated between the dichroic mirror 112 and optical sensor 150 to further narrow the bandwidth of light reaching the optical sensor 150. A set of mounting rods 116 is utilized to rigidly attach the cage cube 113 to a mounting plate 117, which provides structure to attach a coupling mechanism 130 to optical microscope 110.

Coupling mechanism 130 includes a set of constraining bolts 134 that pass through the mounting plate 117 and attach to a sensor head 120, thereby limiting the maximum distance between mounting plate 117 and sensor head 120. The constraining bolts 134 also pass through helical springs 132 that provide compliance between sensor head 120 and optical microscope 110. Helical springs 132 are kept under compression to avoid slack in the coupling mechanism 130. In the absence of an opposing force, the coupling mechanism 130 biases the sensor head 120 to a position in which the color center ensemble is situated beyond the focal plane 119, with respect to the objective 115.

Forces applied to the sensor head 120 are transmitted through the helical springs 132 to the mounting plate 117. Force sensors 136 are situated in the force transmission path between the helical springs 132 and the mounting plate 117. The force sensors 136 are configured to measure forces experienced by the sensor head 120 and generate force data indicative thereof. In an embodiment, force sensors 136 are strain gauges driven by a bridge.

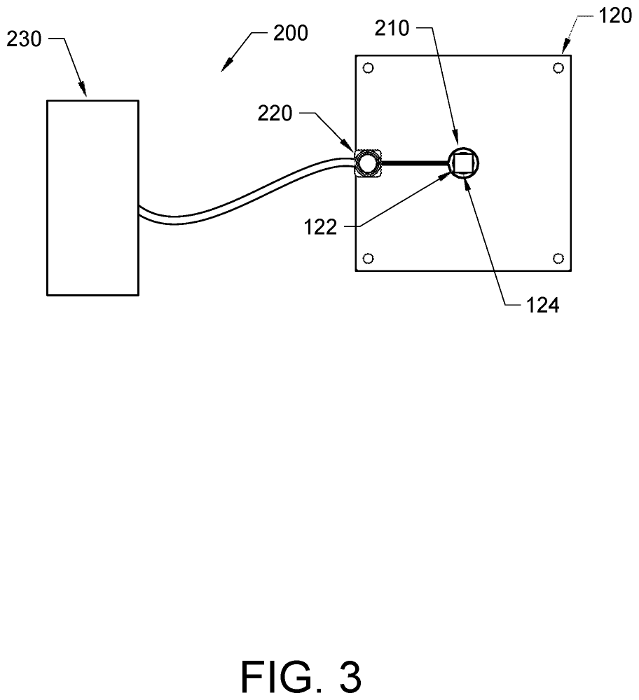

The sensor head 120 includes the solid-state substrate 122 and interacts closely with a battery 170 under investigation. The sensor head 120 includes a through-hole 124 (shown in FIG. 3) above the solid-state substrate 122 that enables the excitation and fluoresced light to pass through. The sensor head 120 is configured to maintain proximity between the color center ensemble and the surface of the battery 170 under consideration during a measurement, which allows magnetic fields at the surface of the battery 170 to influence the spin states of the color center ensemble.

Referring again to FIG. 1A, the solid-state substrate 122 is typically maintained in direct contact with the battery 170 during a measurement. In this embodiment the solid-state substrate 122 is rigidly fixed with respect to the sensor head 120. Accordingly, contact between the solid-state substrate 122 and the battery 170 is maintained by a compressive force of the coupling mechanism 130 and an opposing force applied by an actuator 180. In another embodiment, the sensor head 120 includes a locating feature that maintains both contact with the battery 170 and close proximity between the battery 170 and the solid state substrate 122 during a measurement, for example a thin intermediate protective material on a distal surface of the solid state substrate 122.

As shown in FIG. 1A a test circuit 175 is configured to control the current passing between the cathode and the anode of the battery 170 under inspection. In one embodiment the test circuit 175 comprises a controllable current source and a controllable current sink, along with relay switches for toggling between charging, discharging, and static states. A static state is considered to be a state in which either no current or a negligible amount of current is passing between the cathode and anode of the battery 170. This allows the system to create well-defined current flow states within the battery.

In the charging state, the test circuit 175 configures the relay switches to connect the battery to an external power supply, effectively providing a controlled current to charge the battery. The current source in the test circuit can be adjusted to deliver a specific charging current, ensuring that the charging process is uniform and stable.

In the discharging state, the test circuit 175 reconfigures the relay switches to connect the battery terminals to a controlled resistive load, allowing the battery to discharge according to a predetermined current flow. The current sink in the test circuit ensures that the discharge process remains consistent and measurable.

In the static state, the test circuit 175 opens all connections between the battery 170 terminals so that no current passes between them.

In an embodiment the test circuit 175 is also capable of dynamic current modulation. It can switch between charging and discharging states in predetermined patterns, such as sinusoidal or square wave modulation. This dynamic operation is useful for detecting defects that manifest under time-varying electric fields.

In an embodiment the test circuit 175 utilizes one or more operational amplifiers (op amps) to control the current passing between the battery 170 terminals. In another embodiment test circuit 175 utilizes a proportional-integral-derivative (PID) controller for precise current control.

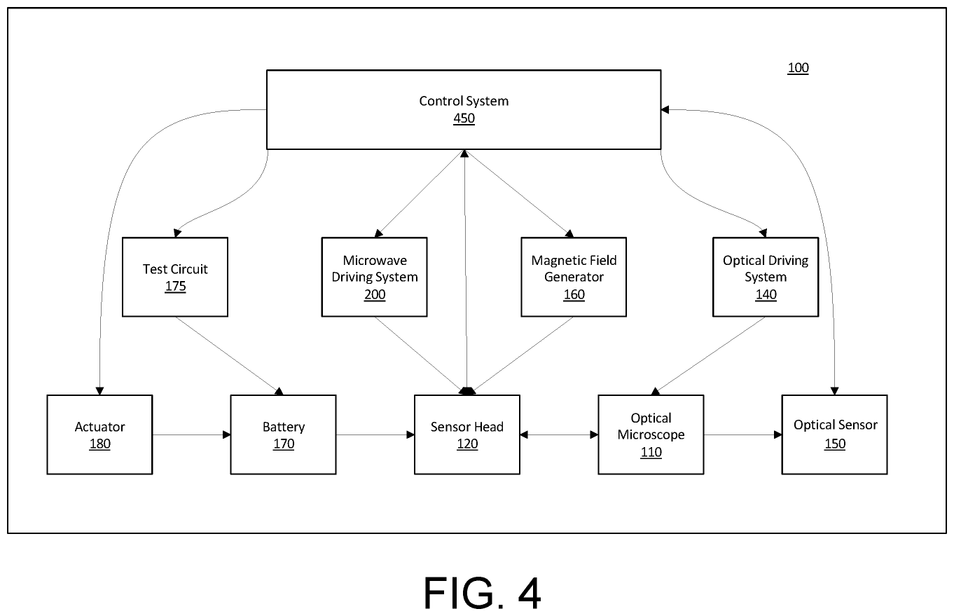

The test circuit 175 can be configured to collect information indicative of the internal electrical characteristics of the battery 170, such as internal resistances and internal capacitances of the battery 170. This information is communicated to a control system 450 (shown in FIG. 4) and can be used in combination with the magnetic field data to identify defects in the battery 170.

The actuator 180 moves the battery 170 relative to the sensor head 120 to enable the surface of the battery 170 to be scanned. Depending on the mode of operation, each position in a scan of the battery 170 can represent a tiled image of a section of the surface of the battery or a single point measurement. In the depicted embodiment the actuator 180 is a Stewart platform. In another embodiment the actuator 180 is a multi-axis stage with serial kinematics. In an embodiment the control system 450 regulates the actuator 180 and facilitates automated adjustments of the battery 170 and the sensor head 120 to maintain contact between the sensor head 120 and the battery 170.

In an embodiment a control system 450 (shown in FIG. 4) regulates the actuator 180 using control signals derived from image data collected by the optical sensor 150 and force data collected by the force sensors 136, facilitating automated adjustments of the battery 170 and the sensor head 120, to position and orient the plane of the ensemble of color centers to be coincident with the focal plane 119, while also maintaining contact between the sensor head 120 and the battery 170. In another embodiment the control system 450 primarily regulates the actuator 180 using control signals derived from image data, and force data indicating anomalous or dangerous forces on the sensor head 120 is utilized to halt operation of the actuator 180.

To facilitate accurate measurements, the actuator 180 effects controlled linear displacements and controlled rotations of the battery 170 and sensor head 120 to bring the plane of the color center ensemble into coincidence with the focal plane 119 of the optical microscope 110, while maintaining contact between them. In this context the direction of controlled linear displacements will typically be dominated by a directional component parallel to the optical axis 118 of the optical microscope 110, such that controlled linear displacements of this nature are substantially along the optical axis 118. In one embodiment the actuator 180 effects such controlled linear displacements and controlled rotations in parallel. In another embodiment the actuator 180 effects such controlled linear displacements and controlled rotations serially.

The magnitude and direction of controlled rotations to bring the plane of the color center ensemble into coincidence with the focal plane 119 will typically be determined by the geometry of the battery 170. For example, in the embodiment depicted in FIG. 1A, the battery 170 has a planar surface in contact with the actuator 180 and an opposing oblique planar surface in contact with the solid-state substrate 122. According to this embodiment, a controlled rotation would be a component of a general transformation to bring the plane of the color center ensemble into coincidence with the focal plane 119. A component of a controlled rotation about an axis parallel to the optical axis 118 is typically inoperative to align the orientation of the plane of the color center ensemble with the focal plane 119, thus a controlled rotation aligning the orientation of the plane of the color center ensemble with the orientation of the focal plane 119 is substantially about an axis perpendicular to the optical axis 118.

The plane of the color center ensemble is considered to be brought into coincidence with the focal plane 119 when it is positioned and oriented such that the focus on the color center ensemble or its feature of interest is maximized to the extent practicable, allowing for clear and distinct observation or measurement, as applicable. This positioning and orienting of the color center ensemble are typically within a tolerance range that accounts for a practical resolution limit of the optical microscope 110 and the optical sensor 150. The specific tolerance range may vary depending on the type of optical microscope 110 and optical sensor 150 used and the nature of the observation or measurement being conducted.

Reference to the plane of the color center ensemble does not imply that the color centers in the ensemble are strictly limited to a single crystallographic plane. Rather the term “plane” in this context is understood to describe an arrangement of color centers that is primarily two-dimensional, but may have a slight thickness, taking into account the technical fabrication capabilities at the time of interpretation

A magnetic field generator 160 applies a bias magnetic field to the color center ensemble. In an embodiment, the magnetic field generator 160 generates a magnetic field configured to facilitate the resolution of the color center magnetic resonances associated with multiple color center axes. In another embodiment, the magnetic field generator 160 generates a magnetic field configured to facilitate the resolution of a color center magnetic resonance associated with a predetermined color center axis. In these embodiments, a color center axis is a crystallographic direction of an individual color center within the lattice structure of the solid-state substrate 122. For example, a nitrogen vacancy color center in a diamond substrate can have one of four color center axes, namely: [111], [11̅1̅], [1̅11̅] and [1̅1̅1]. In the illustrated embodiment, the magnetic field generator 160 is a set of two permanent magnets. In other embodiments magnetic field generator 160 can employ alternative modes of magnetic field generation, including, for example, electromagnets, superconducting magnets, Halbach arrays, and toroidal magnets.

Referring now to FIG. 3, a microwave driving system 200 provides a microwave driving field to the color center ensemble to induce microwave spin transitions. The microwave driving system 200 includes a microwave trace 210, which is attached to the sensor head 120. The microwave trace 210 can be configured as a stripline, a microstrip, a coplanar waveguide, or other patterns that effectively provide a microwave field to the color center ensemble. In certain embodiments, the pattern may be configured to control the spatial uniformity or gradient of the microwave field that interacts with the color centers, enhancing the precision and spatial resolution of the sensor 100. In the illustrated embodiment, both ends of the microwave trace 210 terminate in a single coaxial connector 220.

Microwave driving system 200 further includes a microwave generator 230, which is connected to the microwave trace 210 by way of the coaxial connector 220. The microwave generator 230 delivers a controlled microwave signal to the microwave trace 210. Depending on the application, the controlled microwave signal is typically either a continuous wave or a pulsed microwave field.

FIG. 4 depicts a block diagram illustrating various relationships between components of solid-state sensor 100. In the depicted embodiment, control system 450 is a hub for communication, coordination, processing and control with regard to the various components of solid-state spin sensor 100. In one embodiment, control system 450 is a single computer. In another embodiment, control system 450 is a network of multiple computers and scientific equipment. Depending on the application, control system 450 can be configured to drive various sensing protocols, such as, by way of example, CW ODMR, pulsed ODMR, Ramsey magnetometry, Hahn echo sequences, and T1 relaxometry.

Actuator 180 receives control signals generated by the control system 450, which cause the actuator 180 to apply a force to battery 170. When battery 170 is in contact with sensor head 120 the force is transmitted to sensor head 120 together with a magnetic field associated with the battery 170 that impacts the spin states of the color center ensemble associated with the sensor head 120.

In turn, the force from the actuator 180 is transmitted from sensor head 120 to coupling mechanism 130, and then to the optical microscope 110. Coupling mechanism 130 includes force sensors 136 that measure the force between sensor head 120 and optical microscope 110 and communicate associated force data to control system 450.

Optical driving system 140 receives signals from control system 450 initiating, terminating and adjusting the parameters of the optical driving field for tasks such as measurement readout and optical pumping sequences. On the initiation of optical excitation, light is radiated from the optical driving system 140 to the optical microscope 110 and then illuminates the color center ensemble associated with the sensor head 120 to induce optical transitions.

In a similar fashion microwave driving system 200 receives signals from control system 450 governing the timing and parameters of a microwave driving field. In turn, microwave driving system 200 radiates the microwave driving field to the color center ensemble associated with the sensor head 120 to induce microwave spin transitions.

In the depicted embodiment, the magnetic field generators 160 are electromagnets or another form of magnetic generator capable of selectively controlling the orientation and magnitude of the generated bias magnetic field. As such, in this embodiment the control system 450 directs the magnetic field generator 160 with regard to the parameters of the bias magnetic field, such as, for example, to fine tune a Zeeman splitting.

Control system 450 coordinates these varied signals to effect controlled fluorescence of the color center ensemble conducive to high fidelity optical spin readout. Fluoresced light from the color center ensemble radiates from the sensor head 120 through the optical microscope 110 and associated filters, and into the optical sensor 150, where it is detected by an optical sensor, such as a CMOS or CCD image sensor. Optical sensor 150 transmits the resulting image data to control system 450.

Control system 450 further directs the test circuit 175 to place the battery 170 in a particular state and collects information from the test circuit 175 indicative of the internal electrical characteristics of the battery 170.

Control system 450 also, by way of controlling the actuator 180, directs the tiling of the wide-field maps from region to region of the battery 170 surface, and stitches the multiple maps associated with different regions of the battery 170 into a unified map of a larger region of interest.

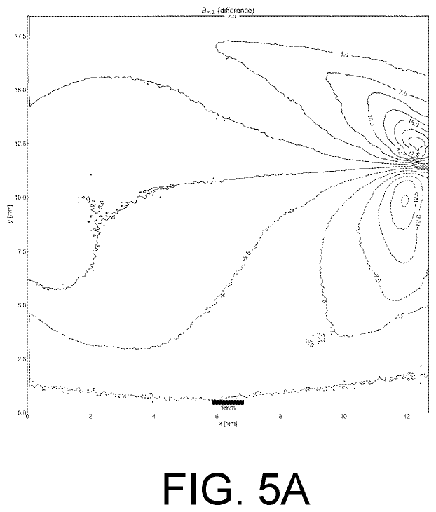

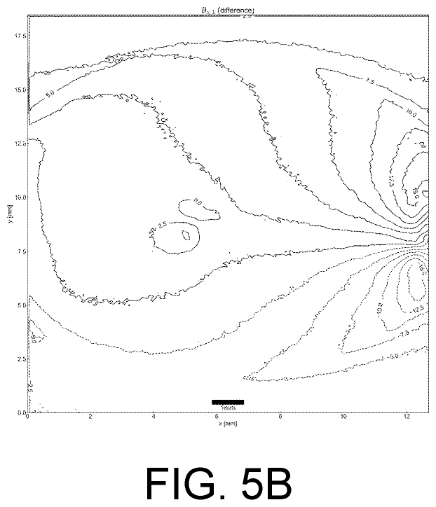

Turning now to FIG. 5A, a spatially resolved map of a magnetic field associated with a defect-free electrode is depicted. The map demonstrates the magnetic field profile under conditions where the electrode is free of any imperfections. The magnetic field is substantially uniformly distributed, providing a baseline against which anomalies can be compared. In this representation, the uniformity of the field indicates the proper flow of current without interruption or irregularities, thus confirming the electrode's defect-free status.

FIG. 5B depicts a spatially resolved map of a magnetic field associated with a defective electrode, which in this case was a 1 mm hole in the electrode. Unlike the defect-free electrode depicted in FIG. 5A, the defective electrode shows significant deviations in the magnetic field profile. The map reveals localized inconsistencies in the magnetic field, indicative of disruptions in current flow indicative of defect in the electrode. In particular the appearance of isolated and incongruous closed contours in the central region of the figure are characteristic of an anomalous dipole, which is indicative of a defect in the electrode.

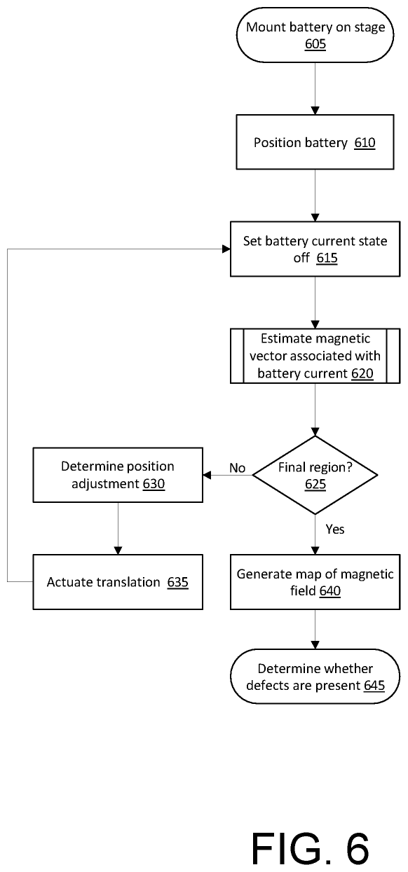

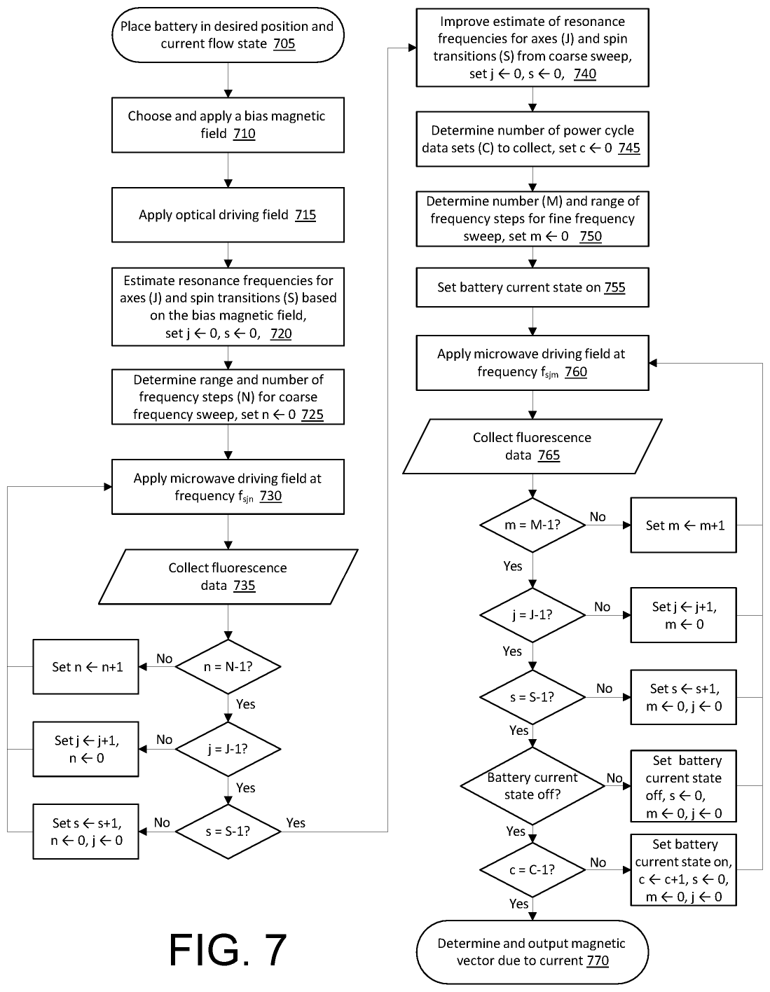

Referring now to FIG. 6, the flow chart illustrates a process for inspecting a battery using a solid-state spin sensor. In the embodiment depicted in FIGS. 6 and 7, single point measurements are used; however, the process can be directly adapted to embodiments that collect multi-pixel images and aggregate the images with image tiling.

The process begins at step 605, where a battery 170 is mounted on an actuator 180 using, for example, a clamping system, a custom stage adapter, or adhesive. Step 605 also includes making electrical connections between the test circuit 175 and both battery 170 terminals.

The actuator 180 is configured to move the battery 170 relative to the sensor head 120 to facilitate the inspection process. At step 610, the battery 170 is positioned relative to the sensor head 120 to measure the magnetic field associated with an initial region of the battery 170 surface.

At step 615, the test circuit 175 prevents the flow of current between the battery 170 terminals.

In step 620 an estimate of the magnetic vector attributable to the current flowing between the terminals of the battery 170 is obtained. This subprocess is depicted and discussed in greater detail in connection with FIG. 7.

A determination is made at step 625 as to whether the magnetic fields at all relevant regions of the battery 170 surface have been measured. In an embodiment the control system 450 makes this determination by comparing the coordinates of the regions of the battery 170 that have been measured to a predetermined set of coordinates to be measured based on the surface geometry of the battery.

If additional regions are required, the process moves to step 630, where position adjustments are determined. In an embodiment the determined adjustment is a translation that aligns a new region of the battery 170 surface with the sensor head 120 for subsequent characterization.

Step 635 involves actuating the actuator 180 to reposition the battery 170 as determined in step 630. In an embodiment the determined adjustment is a translation determined by the control system 450 and effected by the actuator 180 that aligns a new region of the battery 170 surface with the sensor head 120 for subsequent characterization. Following this adjustment, the process cycles back to step 615 and repeats the measurement steps for the new region.

When the inspected region is determined to be the final one, the process proceeds to generating a map of the magnetic field associated with the battery current at step 640.

In the final step 645, the resulting map is then used to determine whether defects are present in the battery 170. In an embodiment this step involves identification of features in the map of the magnetic field associated with the battery current that are indicative of defects. In an embodiment the control system 450 is programmed to identify anomalous dipoles in this map as compared to a reference map of a defect-free battery 170, such as the anomalous dipoles indicated by the closed contours in the central region of FIG. 5B, which are absent from FIG. 5A.

FIG. 7 illustrates a subprocess for estimating a magnetic vector attributable to a current flowing between the terminals of a battery 170.

The process begins at step 705, where the battery is placed in a desired position and current flow state, as detailed in FIG. 6.

At step 710, a bias magnetic field is applied to the area of interest by the magnetic field generator 160. In the depicted embodiment, the bias magnetic field is set to be significantly larger than the magnetic field of the battery to enhance clarity and interpretability of the data. In an embodiment the magnitude of the bias magnetic field is ten times larger than the largest expected magnitude of the magnetic field from the battery. In another embodiment the bias magnetic field is approximately 1 mT and the static magnetic field is less than 100 μT.

Following the application of the bias magnetic field, step 715 involves applying an optical driving field by the optical driving system 140. In this context, the optical driving field is used to excite the color center ensemble, thereby initiating the process by which fluorescence data can be collected.

In an embodiment utilizing optically detected magnetic resonance (ODMR) with NV centers in a single crystal diamond, the relationship between the resonance frequencies (fₛⱼ) of NV centers oriented along one of the four color center axes and having one of two possible spin states, can approximated by

$${f}_{sj} = 2.87 GHz + {( - 1 )}^{s} ( 28 GHz / T ) \times ( {B}_{0} + {B}_{bat} ) \cdot {u}_{j}$$

where B₀ is the bias magnetic field vector; B_{bat} is the magnetic field vector from the battery 170 without current passing between the terminals; uⱼ, with j∈{0,1,2,3}, are unit vectors of the color center axes; and s∈{0,1}represents the spin states of the NV centers with magnetic moments in alignment and anti-alignment, respectively, with B₀. In this embodiment, the bias magnetic field vector and the orientation of the color center axes are known.

In this embodiment, up to eight resonant frequencies can be identified in the ODMR spectra. Depending on assumptions that can be made regarding the components of B_{bat}, a smaller subset of these frequencies may be probed. In another embodiment all eight of the resonant frequencies are probed and the additional information is used to correct for secondary factors such as crystal stress.

In step 720, the resonance frequencies expected for a set of color center axes (J) and spin transitions (S) based on the bias magnetic field is estimated and provides a center point for the initial coarse frequency sweep. Counters for each color center axis (j) and spin transition (s) to be probed are initialized to zero.

In step 725, the number of frequency steps (N) for a coarse frequency sweep is determined, and the sweep counter (n) is initialized to zero. For example, in the embodiment utilizing NV centers, if a battery 170 is expected to have a range of static magnetic fields of ±150 μT, the initial coarse sweep would cover 8.4 MHz (300 μT×28 GHz/T) centered at the resonant frequency expected due to the bias magnetic field alone. In this embodiment the spacing between samples is chosen to be two to three times finer than the NV ODMR linewidth, which is typically approximately 0.1 MHz to 1 MHz.

Subsequently, a microwave driving field at a frequency associated with a given spin transition (s), color center axis (j) and coarse sweep iteration (n), denoted fₛⱼₙ, is applied to the color center ensemble by the microwave driving system 200 at step 730. At resonant frequencies the microwave field induces transitions in the color centers that are dependent on the local magnetic field, which in turn affects the fluorescence emitted by the color centers.

At step 735, fluorescence data is collected by the optical sensor 150 and associated with the parameters of the system during collection.

After collecting data for each of the S×J×N parameter iterations, at step 740 the resulting spectra are analyzed to estimate the S×J resonant frequencies, which are indicative of the magnetic vector B₀+B_{bat}. This analysis can include, for example, peak fitting to roughly estimate the resonance frequency for each color center axis and spin state combination being probed. Counters for each color center axis (j) and spin transition (s) to be investigated are again initialized to zero.

In step 745 the number of power cycle data sets (C) to be collected is determined. Power cycle data sets are pairs of densely sampled resonance frequency measurements with and without current flowing between the battery 170 terminals, which are taken in close temporal proximity to reduce the impact of low frequency noise on the measurement of the magnetic vector due to the battery 170 current. Furthermore, the collection of multiple power cycle data sets (C) can help reduce the impact of high frequency noise.

Step 750 involves determining the number (M) and range of frequency steps for a fine frequency sweep, initializing the step counter (m) to zero. The fine sweep aims to hone in on the precise resonant frequencies with greater accuracy than the coarse scan. This scan is denser and centered on the improved estimates from step 740.

With the refined parameters, the process applies the microwave driving field at the finer frequency increments, labeled fₛⱼₘ, at step 750. This precise application narrows the search window for the resonant frequencies by targeting smaller, more specific segments around the initial coarse estimates.

In step 755 the test circuit 175 allows current to flow between the battery 170 terminals. In an embodiment, the test circuit 175 connects the terminals over a set of passive components configured to reduce noise. In another embodiment the test circuit 175 utilizes a PID controller to precisely control the current passing through the battery 170 terminals.

Subsequently, a microwave driving field at a frequency associated with a given spin transition (s), color center axis (j) and fine sweep iteration (m), denoted fₛⱼₘ, is applied to the color center ensemble by the microwave driving system 200 at step 760.

In step 765 fluorescence data is collected by the optical sensor 150 and associated with the parameters of the system during collection.

After collecting data for each of the 2×C×S×J×M parameter iterations, at step 770 an estimate of the magnetic vector due to the battery 170 current is determined. In an embodiment utilizing NV centers, this determination is made from comparing the power cycle data set measurements consisting of the pairs of resonance frequency measurements with current (fₛⱼ⁺) and without current (fₛⱼ⁰), which can be approximated by

$${f}_{sj}^{0} = 2.87 GHz + {( - 1 )}^{s} ( 28 GHz / T ) \times ( {B}_{0} + {B}_{bat} ) \cdot {u}_{j}$$

$${f}_{sj}^{+} = 2.87 GHz + {( - 1 )}^{s} ( 28 GHz / T ) \times ( {B}_{0} + {B}_{bat} + {B}_{cur} ) \cdot {u}_{j}$$

where B_{cur} is the magnetic vector due to current flowing between the terminals of the battery 170. In this embodiment B₀ and uⱼ are known, and solutions for the components of B_{cur} are overdetermined when all eight resonance frequencies are probed. In this scenario, the additional information can be used to correct for secondary factors such as crystal stress. Moreover, when multiple power cycle data sets are collected (C>1), the resulting B_{cur} calculations can be averaged over or otherwise aggregated to improve the estimate.

Although exemplary embodiments of the present disclosure have been described in detail, those skilled in the art will appreciate that various changes, substitutions and improvements disclosed herein may be made without departing from the spirit and scope of the disclosure in its broadest form. By way of example, and without limiting the generality of the foregoing, the disclosed systems and methods relating to the measurement of a magnetic field associated with a battery 170 may be applied measuring other physical properties, such as electric field and temperature, without departing from the essence of the disclosure.

The description and drawings in the present disclosure should not be read as implying that any particular element, step, function or advantage is an essential element that must be included in the claim scope. The scope of patented subject matter is defined only by the allowed claims.

What is claimed is:

1. A system for detecting defects in a battery comprising:
a test circuit configured to control a current passing between the cathode and anode of a battery;
a solid state substrate;
a defect embedded in the solid state substrate;
a magnetic field generator configured to produce a bias magnetic field at the defect;
an optical driving system configured to optically excite the defect;
an optical sensor configured to measure a fluorescence intensity of the defect; and
a control system configured to:
receive signals from the optical sensor indicative of the fluorescence intensity,
generate, based on the received signals, a spatially resolved map of a magnetic field produced by the current, and
identify, based on characteristics of the spatially resolved map, defects in the battery.

2. The system of claim 1, wherein the solid state substrate is a diamond, and the defect is a nitrogen-vacancy center.

3. The system of claim 1, wherein the control system is further configured to receive data indicative of an electrical characteristic of the battery from the test circuit, and the identification of defects in the battery is further based on the electrical characteristic.

4. The system of claim 1 further comprising a microwave driving system, wherein:
the control system is further configured to:
perform a sweep of a microwave drive frequency range at multiple battery positions of the battery, and
monitor the fluorescence intensity to determine a resonance frequency at each battery position, and
the spatially resolved map is generated based on the determined resonance frequencies.

5. The system of claim 1, wherein the control system is further configured to:
acquire a spatially resolved map of a static magnetic field while no current is passing between the cathode and the anode; and
acquire a spatially resolved map of a dynamic magnetic field while the current is passing between the cathode and the anode;
wherein the spatially resolved map of the magnetic field produced by the current is generated based on the subtraction of the spatially resolved map of the static magnetic field from the spatially resolved map of the dynamic magnetic field.

6. The system of claim 1, wherein the defect is a color center, and the control system is further configured to measure a plurality of points in the magnetic field produced by the current.

7. The system of claim 1, wherein the defect is an ensemble of color centers, and the optical sensor captures wide-field images of the fluorescence intensity of the ensemble of color centers.

8. The system of claim 1, wherein:
the control system includes a machine learning algorithm, and
the control system is further configured to:
use the machine learning algorithm in the identification of defects in the battery, and
generate, based on the spatially resolved map, a training data set to improve the machine learning algorithm.

9. The system of claim 1, further comprising a three-axis actuator, wherein the control system is configured to:
actuate the three-axis actuator to scan the battery under the solid state substrate, and
collect magnetic field data at multiple positions to generate a tiled image of the magnetic field distribution across the battery.

10. The system of claim 5, wherein the static magnetic field map includes a largest static magnetic field magnitude and the magnitude of the bias magnetic field is approximately ten times larger than the largest static magnetic field magnitude.

11. The system of claim 1, wherein:
the control system is configured to analyze multiple components of the magnetic field produced by the current, and
the spatially resolved map is a spatially resolved vector magnetic field map.

12. A method for detecting defects in a battery using a quantum sensor, comprising:
controlling a current between a cathode and an anode of the battery using a test circuit;
generating a bias magnetic field at a defect embedded in a solid state substrate using a magnetic field generator;
optically exciting the defect with an optical driving system;
measuring a fluorescence intensity of the defect with an optical sensor;
receiving signals from the optical sensor indicative of the fluorescence intensity;
generating, based on the received signals, a spatially resolved map of a magnetic field produced by the current; and
identifying defects in the battery based on characteristics of the spatially resolved map.

13. The method of claim 12, further comprising correcting for static magnetic fields associated with magnetized components of the battery.

14. The method of claim 12, further comprising:
acquiring a static magnetic field map while no current is passing between the cathode and anode; and
subtracting the static magnetic field map from the spatially resolved map.

15. The method of claim 12, wherein the defect embedded in the solid state substrate is a color center, and the method further comprises measuring a plurality of points in the magnetic field produced by the current.

16. The method of claim 12, further comprising using a microwave driving system to induce microwave spin transitions in the defect.

17. A method for evaluating structural integrity of a battery using a quantum sensor, comprising:
mounting the battery on a actuator with one or more axes;
positioning a surface of the battery proximate to a defect embedded in a solid state substrate;
controlling a current between a cathode and an anode of the battery using a test circuit;
generating a bias magnetic field at the defect using a magnetic field generator;
optically exciting the defect by illuminating the defect with light from an optical driving system;
measuring a fluorescence intensity of the defect using an optical sensor;
generating a spatially resolved map of a magnetic field produced by the current; and
analyzing the spatially resolved map to identify defects in the battery.

18. The method of claim 17, further comprising varying the current flow in a predetermined pattern to detect defects associated with time-varying currents.

19. The method of claim 17, further comprising:
actuating the actuator to change the position of the surface relative to the defect after measuring the fluorescence intensity; and
measuring a second fluorescence intensity of the defect after actuating the actuator.

20. The method of claim 17, further comprising using a machine learning algorithm to predict, based on the spatially resolved map, the presence of defects.
